(19) United States
(12) Patent Application Publication
(10) Pub. No.: US 2026/0179874 A1
(43) Pub. Date: Jun. 25, 2026

(54) CHARGED PARTICLE BEAM DEVICE, OBSERVATION CONDITION SETTING METHOD, AND PROGRAM

(71) Applicant: HITACHI HIGH-TECH CORPORATION, Minato-ku, Tokyo (JP)

(72) Inventors: Kazuo OTSUGA, Tokyo (JP); Heita KIMIZUKA, Tokyo (JP); Makoto SAKAKIBARA, Tokyo (JP)

(21) Appl. No.: 18/854,644

(22) PCT Filed: Jun. 6, 2022
(86) PCT No.: PCT/JP2022/022795

§ 371 Date: Oct. 7, 2024

(51) Int. Cl. H01J 37/26; H01J 37/02; H01J 37/147; H01J 37/20; H01J 37/244; H01J 37/28

(52) U.S. Cl. CPC H01J 37/265; H01J 37/026; H01J 37/147; H01J 37/20; H01J 37/244; H01J 37/28

(57) ABSTRACT

A charged particle beam device for observing a sample by periodically irradiating the sample with a pulsed charged particle beam includes a control device configured to control irradiation using the pulsed charged particle beam and detection of a signal of an emitted electron based on an observation condition. The control device calculates an irradiation period, a scanning speed, and a pulse width of the pulsed charged particle beam and a detection timing of the signal of the emitted electron based on a current of the charged particle beam emitted from the particle source and an electrostatic capacity and an electrical resistance of the sample, and sets the observation condition including the current of the charged particle beam, the irradiation period, the scanning speed, and the pulse width of the pulsed charged particle beam, and the detection timing of the signal of the emitted electron.

### TECHNICAL FIELD

The present invention relates to a measuring device that observes a sample using a charged particle beam, and particularly to an electron microscope.

### BACKGROUND ART

In the field of electronics, miniaturization and three-dimensionalization of sizes of devices such as semiconductors are progressing year by year. Accordingly, it is required to obtain information on electric characteristics caused not only by a surface of a semiconductor but also by a structure of a bottom portion of a diffusion phase, or the like.

One method for observing a surface of a semiconductor is to use a scanning electron microscope. In the following description, the scanning electron microscope is also referred to as SEM.

A technique described in PTL 1 is known as a method for measuring electrical characteristics using an SEM. PTL 1 describes “a measuring device for observing a sample by irradiating the sample with a charged particle beam, the measuring device including: a particle source configured to output the charged particle beam; a lens configured to focus the charged particle beam; a detector configured to detect a signal of an emitted electron emitted from the sample irradiated with the charged particle beam; and a control device configured to control the output of the charged particle beam and the detection of the signal of the emitted electron based on an observation condition, in which the control device sets, as the observation condition, a first parameter for controlling an irradiation period of the charged particle beam, a second parameter for controlling a pulse width of the pulsed charged particle beam, and a third parameter for controlling a detection timing of the signal of the emitted electron within an irradiation time of the pulsed charged particle beam, and the third parameter is determined based on a difference in intensity between signals of a plurality of emitted electrons emitted from an irradiation position of the charged particle beam”.

### CITATION LIST

### Patent Literature

PTL 1: JP2018-137160A

### SUMMARY OF INVENTION

### Technical Problem

A range (an observation range) of electric characteristics that can be observed using an SEM depends on an observation condition. One observation condition is an irradiation current (a probe current) of an electron beam. Since it takes time to change the irradiation current, the throughput of inspection decreases.

An object of the invention is to provide a technique for setting an observation condition that implements a desired observation range while keeping an irradiation current of an electron beam constant.

### Solution to Problem

A representative example of the invention disclosed in the present application is as follows. That is, the representative example is a charged particle beam device for observing a sample by periodically irradiating the sample with a pulsed charged particle beam. The charged particle beam device includes: a particle source configured to output the charged particle beam; a lens configured to focus the charged particle beam; a detector configured to detect a signal of an emitted electron emitted from the sample irradiated with the charged particle beam; and a control device configured to control the irradiation using the pulsed charged particle beam and the detection of the signal of the emitted electron based on an observation condition. The control device calculates an irradiation period, a scanning speed, and a pulse width of the pulsed charged particle beam and a detection timing of the signal of the emitted electron based on a current of the charged particle beam emitted from the particle source and an electrostatic capacity and an electrical resistance of the sample, and sets the observation condition including the current of the charged particle beam, the irradiation period, the scanning speed, and the pulse width of the pulsed charged particle beam, and the detection timing of the signal of the emitted electron.

### Advantageous Effects of Invention

According to the invention, an observation condition that implements a desired observation range can be set while keeping an irradiation current of an electron beam constant. The problems, configurations, and effects other than those described above will become apparent in the following description of embodiments.

### BRIEF DESCRIPTION OF DRAWINGS

FIG. 1 is a diagram illustrating an example of a configuration of a scanning electron microscope of Embodiment 1.

FIG. 2A is a diagram illustrating an example of a sample observed using the scanning electron microscope of Embodiment 1.

FIG. 2B is a diagram illustrating an example of the sample observed using the scanning electron microscope of Embodiment 1.

FIG. 3A is a diagram illustrating an example of a control signal of the scanning electron microscope of Embodiment 1.

FIG. 3B is a diagram illustrating an example of the control signal of the scanning electron microscope of Embodiment 1.

FIG. 4A is a diagram illustrating an example of observation range information of Embodiment 1.

FIG. 4B is a diagram illustrating an example of the observation range information of Embodiment 1.

FIG. 4C is a diagram illustrating an example of the observation range information of Embodiment 1.

FIG. 5 is a diagram illustrating an example of a screen displayed on an output device of Embodiment 1.

FIG. 6 is a flowchart illustrating a process executed by the scanning electron microscope of Embodiment 1 when setting an observation condition.

FIG. 7 is a diagram illustrating an example of a screen displayed on an output device of Embodiment 2.

FIG. 8 is a diagram illustrating an example of a control signal of a scanning electron microscope of Embodiment 2.

FIG. 9 is a diagram illustrating an example of a screen displayed on an output device of Embodiment 3.

FIG. 10 is a flowchart illustrating a process executed by a scanning electron microscope of Embodiment 3 when setting an observation condition.

FIG. 11 is a diagram illustrating an example of a screen displayed on an output device of Embodiment 4.

FIG. 12 is a diagram illustrating an example of a potential distribution used in an observation simulation in Embodiment 4.

FIG. 13 is a flowchart illustrating a process executed by a scanning electron microscope of Embodiment 4 when setting an observation condition.

FIG. 14 is a diagram illustrating an example of a configuration of a scanning electron microscope of Embodiment 5.

### DESCRIPTION OF EMBODIMENTS

Hereinafter, embodiments of the invention will be described with reference to the drawings. However, the invention is not to be construed as being limited to the description of the following embodiment. It will be easily understood by those skilled in the art that the specific configuration can be changed without departing from the spirit or scope of the invention.

In the configurations of the invention described below, the same or similar configurations or functions are denoted by the same reference numerals, and a redundant description will be omitted.

Notations “first”, “second”, “third”, and the like in the present specification and the like are provided to identify components, and do not necessarily limit the number or the order.

In order to facilitate understanding of the invention, the position, size, shape, range, and the like of each configuration shown in the drawings and the like may not represent the actual position, size, shape, range, and the like. Therefore, the invention is not limited to the positions, sizes, shapes, ranges, and the like disclosed in the drawings.

### Embodiment 1

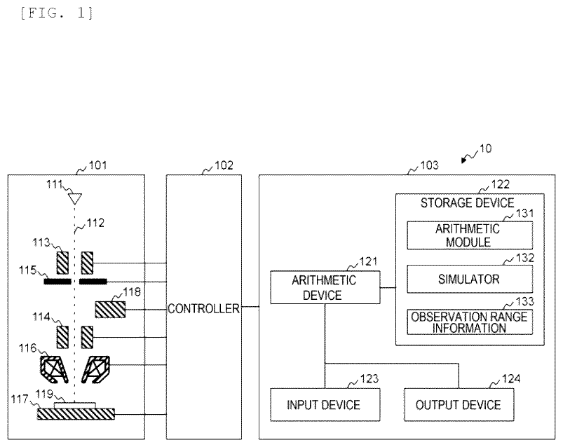

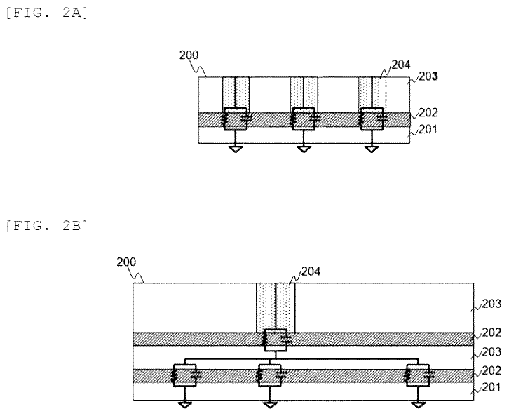

FIG. 1 is a diagram illustrating an example of a configuration of a scanning electron microscope of Embodiment 1. FIGS. 2A and 2B are diagrams illustrating an example of a sample observed using the scanning electron microscope of Embodiment 1.

A scanning electron microscope 10 includes an electron optical system lens barrel 101, a controller 102, and a computer 103.

The electron optical system lens barrel 101 includes an electron gun 111, deflectors 113 and 114, an aperture 115, an objective lens 116, a detector 118, and a sample holder 117.

The electron gun 111 outputs a primary electron beam 112. In Embodiment 1, a sample 119 is irradiated with a pulsed electron beam as the primary electron beam 112. An output of the pulsed electron beam may be implemented under control of the deflector 113 corresponding to a pulsed deflector, or may be implemented by using the electron gun 111 capable of outputting a pulsed electron beam.

A focus and the like of the primary electron beam 112 can be adjusted when the primary electron beam 112 passes through the deflector 113 and the objective lens 116. A trajectory of the primary electron beam 112 is deflected when the primary electron beam 112 passes through the deflector 114, and the primary electron beam 112 two-dimensionally scans the sample 119. An emitted electron emitted from the sample 119 irradiated with the primary electron beam 112 is detected by the detector 118. A signal of the emitted electron detected by the detector 118 is processed by the computer 103. A two-dimensional image corresponding to an irradiation position of the primary electron beam 112 is displayed on an output device 124.

The sample holder 117 includes a stage on which the sample 119 is placed. The stage can perform tilt control and movement control in three-dimensional directions (X, Y, and Z axes).

Here, the sample 119 is assumed to be a semiconductor substrate 200 as illustrated in FIGS. 2A and 2B.

The semiconductor substrate 200 includes a conductor 201, insulators 202 and 203, and a contact plug 204. A netlist representing an equivalent circuit of a device structure of the semiconductor substrate 200 is superimposed on the semiconductor substrate 200.

The scanning electron microscope 10 of Embodiment 1 can observe not only electric characteristics (an electrical resistance and an electrostatic capacity) of the semiconductor substrate 200 having a small number of stacked layers as illustrated in FIG. 2A, but also electric characteristics of the semiconductor substrate 200 having a large number of stacked layers as illustrated in FIG. 2B. The semiconductor substrate 200 illustrated in FIGS. 2A and 2B is an example and is not limited thereto.

The controller 102 controls the components of the electron optical system lens barrel 101 in accordance with instructions from the computer 103. The controller 102 is, for example, a microcomputer or a computer.

The computer 103 includes an arithmetic device 121, a storage device 122, an input device 123, and the output device 124. The computer 103 may include a storage medium such as a hard disk drive (HDD) and a solid state drive (SSD).

The arithmetic device 121 executes a predetermined arithmetic process according to a program stored in the storage device 122. The arithmetic device 121 is, for example, a central processing unit (CPU), a field programmable gate array (FPGA), or a graphics processing unit (GPU).

The storage device 122 stores a program executed by the arithmetic device 121 and data used by the program. The storage device 122 includes a temporary storage area such as a work area used by the program. The storage device 122 may be, for example, a memory. The program and data stored in the storage device 122 will be described later.

The input device 123 is a device for inputting data, and includes a keyboard, a mouse, a touch panel, and the like. The output device 124 is a device for outputting data, and includes a touch panel, a display, and the like.

The storage device 122 stores a program for implementing an arithmetic module 131 and a simulator 132, and also stores observation range information 133. The storage device 122 may store a program and information (not illustrated).

The arithmetic module 131 sets an observation condition for controlling irradiation using a pulsed electron beam and detection of a signal of an emitted electron. The arithmetic module 131 generates an image (a voltage contrast image) based on the signal of the emitted electron. The arithmetic module 131 may be divided into a plurality of modules for each function.

Here, the observation condition includes an acceleration voltage, an irradiation current (a probe current), a pulse width (an irradiation time), an irradiation period, and a detection timing. The observation condition may include elements other than those described above, such as a scan range and a way of moving the primary electron beam 112.

The simulator 132 executes a device simulation for estimating electric characteristics of the sample 119 and an observation simulation for estimating a signal of an emitted electron. A process using the simulator 132 will be described in Embodiment 4.

The observation range information 133 is information on an observation range for the scanning electron microscope 10.

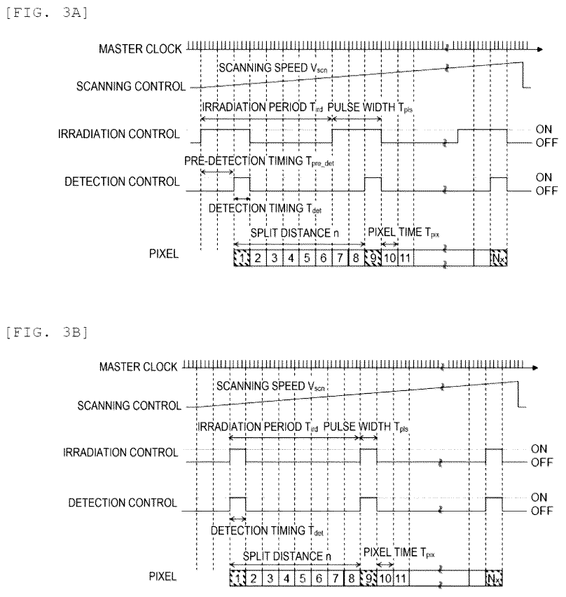

FIGS. 3A and 3B are diagrams illustrating an example of a control signal of the scanning electron microscope 10 of Embodiment 1.

The scanning electron microscope 10 starts scanning from, for example, the upper left of the sample 119 and scans the primary electron beam 112 to the lower left. Accordingly, charge control of the sample 119 and observation of a transient state of charge of the sample 119 can be implemented.

A master clock is a signal serving as a reference for the operation of each device. A control signal, which will be described later, is controlled so as to be synchronized with the master clock.

A pixel represents a pixel of the sample 119 in an X direction. A variable representing a pixel interval (a split distance) at which the sample 119 is irradiated with a pulsed electron beam is denoted by n, and a variable representing a time of one pixel is denoted by Tₚᵢₓ.

A scanning control signal is a control signal for controlling the deflector 113 to adjust the irradiation position of the primary electron beam 112. Here, a variable representing a scanning speed of the primary electron beam 112 in an X direction is denoted by V_{scn}.

As the scanning control signal increases, the primary electron beam 112 moves on the sample 119 from the left end to the right end. When the primary electron beam 112 reaches the right end, that is, when an intensity of a polarizer control signal changes to an initial value, the scanning electron microscope 10 moves to scan lines spaced at a regular interval in a Y direction, and then irradiates the sample 119 with a pulsed electron beam from the left end to the right end.

An irradiation control signal is a control signal for emitting a pulsed electron beam. The irradiation control signal is determined based on an irradiation period and a pulse width. In the following description, a variable representing the irradiation period is denoted by T_{ird}, and a variable representing the pulse width is denoted by Tₚₗₛ.

A detection control signal is a control signal for adjusting a timing of detecting an emitted electron. The computer 103 performs sampling so as to detect an emitted electron once at any timing during the irradiation using the pulsed electron beam. The detection control signal is determined based on a pre-detection timing and a detection timing. The pre-detection timing represents a time interval from the irradiation using the pulsed electron beam to the start of detection. In FIG. 3B, the pre-detection timing is 0. The detection timing represents a time interval at which an emitted electron is detected. Hereinafter, a variable representing the pre-detection timing is denoted by T_{pre_det}, and a variable representing the detection timing is denoted by Tₚᵣₑ.

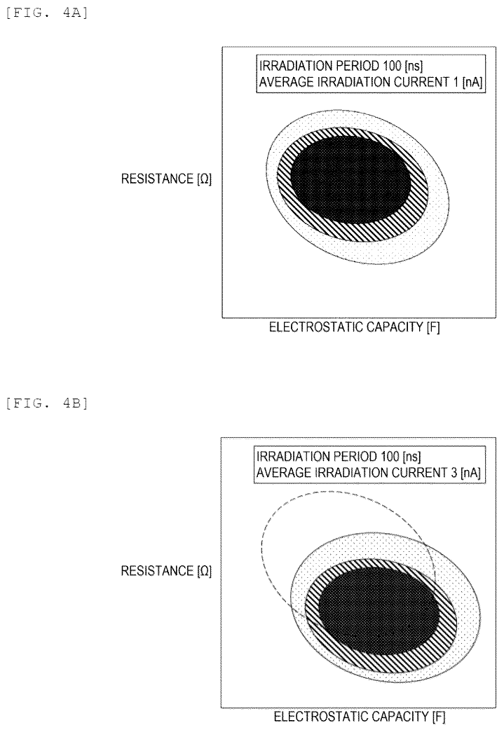

FIGS. 4A, 4B, and 4C are diagrams illustrating an example of the observation range information 133 of

### Embodiment 1

The observation range information 133 stores an observation range map 400 as illustrated in FIGS. 4A, 4B, and 4C. The observation range map 400 represents observation accuracy of the scanning electron microscope 10 for a combination of an electrical resistance and an electrostatic capacity. In FIGS. 4A, 4B, and 4C, the darker the color, the higher the observation accuracy.

The observation range map 400 is managed in association with characteristics (a device structure and a material) of the sample 119, an irradiation current, an irradiation period, and an average irradiation current. It is assumed that the characteristics of the sample 119 and the irradiation currents which are associated with the observation range map 400 illustrated in FIGS. 4A, 4B, and 4C are each the same.

Here, the average irradiation current represents a current to be applied to the sample 119 in one period, and can be calculated by multiplying a duty ratio by an irradiation current as in Formula (1), for example. Here, Iₐᵥₑ is a variable representing the average irradiation current, and Iₚ is a variable representing the irradiation current.

$$\begin{matrix}[ Formula 1 ] & \\ {I}_{ave} = \frac{{T}_{pls}}{{T}_{ird}} {I}_{p} & ( 1 )\end{matrix}$$

It is found that when the irradiation current is constant, the observation range can be expanded as follows by adjusting the average irradiation current and the irradiation period.

(Characteristic 1) As shown in FIG. 4B, it is found that, by increasing the average irradiation current, the observation range moves in a direction in which the electrostatic capacity increases and the electrical resistance decreases.

(Characteristic 2) As shown in FIG. 4C, it is found that, by decreasing the irradiation period, the observation range moves in a direction in which the electrostatic capacity decreases.

The arithmetic module 131 of Embodiment 1 calculates the irradiation period and the average irradiation current based on the electric characteristics of the sample 119, and calculates parameters (an irradiation period, a scanning speed, and a pulse width) for the irradiation control signal and parameters (a pre-detection timing and a detection timing) for the detection control signal based on the irradiation period and the average irradiation current.

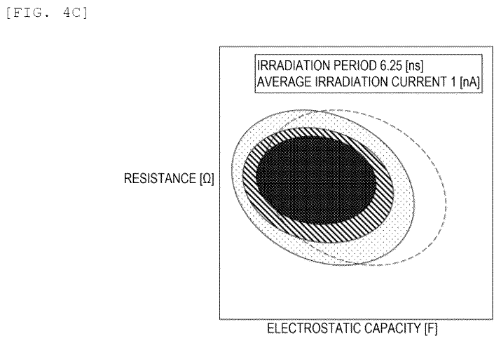

FIG. 5 is a diagram illustrating an example of a screen displayed on the output device 124 of Embodiment 1.

The screen 500 is a screen that is displayed when setting the observation condition, and includes an input button 501, an input field 502, a setting button 503, a display field 504, an image acquisition button 505, and a display field 506.

The input button 501 is an operation button for instructing calculation of the parameters for the irradiation control signal and the parameters for the detection control signal using values input to the input field 502. When the input button 501 is operated, the computer 103 executes an observation condition setting process using the values input in the input field 502.

The input field 502 is a field for inputting values used to calculate the parameters for the irradiation control signal and the parameters for the detection control signal. Specifically, the input field 502 includes boxes for inputting an acceleration voltage, an irradiation current, a split distance, a magnification (a pixel distance), an electrostatic capacity, and an electrical resistance.

The setting button 503 is an operation button for setting the observation condition. When receiving an operation of the setting button 503, the scanning electron microscope 10 of Embodiment 1 irradiates the sample 119 with a pulsed electron beam based on the observation condition, and records, in the storage device 122, data indicating a time change of a signal of an emitted electron. The screen 500 may include a field for displaying a graph of the time change of a signal of an emitted electron.

The display field 504 is a field for displaying the calculated parameters for the irradiation control signal and parameters for the detection control signal.

The image acquisition button 505 is an operation button for instructing generation of a voltage contrast image. The display field 506 is a region for displaying the voltage contrast image.

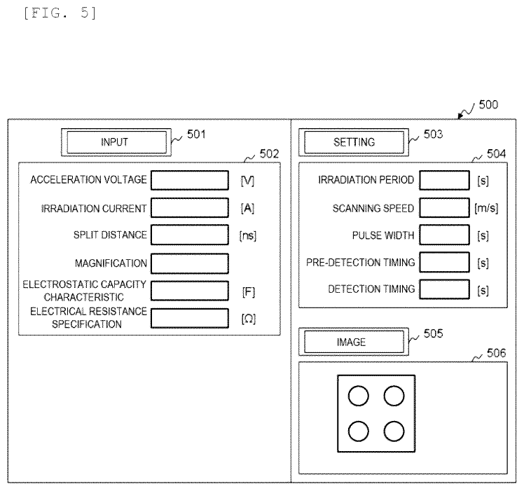

FIG. 6 is a flowchart illustrating a process executed by the scanning electron microscope 10 of Embodiment 1 when setting an observation condition.

When the input button 501 is operated, the scanning electron microscope 10 starts the process described below.

The computer 103 acquires input information including values input to the input field 502 (step S101).

The computer 103 calculates an irradiation period and an average irradiation current of a pulsed electron beam using an electrostatic capacity and electrical resistance included in the input information and the observation range information 133 (step S102). Specifically, the following process is executed.

(S102-1) The computer 103 specifies, based on an irradiation current included in the input information, the observation range map 400 to be referred to. When characteristics (a device structure and a material) of the sample 119 are input, such information may also be used.

(S102-3) The computer 103 refers to the specified observation range map 400, and selects the observation range map 400 in which a difference between a center of gravity of a region with the highest accuracy and a combination of the electrostatic capacity and electrical resistance included in the input information is small. That is, the observation range map 400 in which a distance between two points in an (electrostatic capacity-electrical resistance) space is minimum is selected. The computer 103 acquires an irradiation period and an average irradiation current which are associated with the selected observation range map 400.

The process in step S102 has been described above.

The computer 103 calculates a scanning speed, a pulse width, and a detection timing using the irradiation period and the average irradiation current (step S103).

Specifically, each value can be calculated using the following formula.

The scanning speed can be calculated using, for example, Formula (2).

$$\begin{matrix}[ Formula 2 ] & \\ {V}_{scn} = \frac{{L}_{pix}}{{T}_{pix}} {I}_{p} = \frac{n \times {L}_{pix}}{{T}_{ird}} & ( 2 )\end{matrix}$$

The pulse width can be calculated using, for example, Formula (3).

$$\begin{matrix}[ Formula 3 ] & \\ {T}_{pls} = \frac{{I}_{ave} \times {T}_{ird}}{{I}_{p}} & ( 3 )\end{matrix}$$

The detection timing can be calculated using, for example, Formula (4).

$$\begin{matrix}[ Formula 4 ] & \\ {T}_{pre \_ det} = {T}_{pls} - {T}_{det} & ( 4 )\end{matrix}$$

When receiving the operation of the setting button 503, the computer 103 transmits an observation instruction including the observation condition to the controller 102 to irradiate the sample 109 with a pulsed electron beam (step S104). When receiving the observation instruction, the controller 102 controls the electron optical system lens barrel 101 to periodically irradiate the sample 119 with a pulsed electron beam having a predetermined pulse width and measure an emitted electron.

The computer 103 acquires, via the controller 102, an observation result such as data indicating a time change of a signal of an emitted electron detected by the detector 118 (step S105), and records the observation result in the storage device 122.

The computer 103 acquires a detection signal by sampling, based on the parameters for the detection control signal, the data indicating a time change of a signal of an emitted electron (step S106). The computer 103 generates a voltage contrast image using the detection signal.

According to Embodiment 1, the parameters (the irradiation period, the scanning speed, and the pulse width) for the irradiation control signal and the parameters (the pre-detection timing and the detection timing) for the detection control signal can be calculated using the electrostatic capacity and the electrical resistance.

According to the method of Embodiment 1, the observation range can be expanded while keeping the irradiation current fixed. Therefore, a decrease in throughput due to a change in irradiation current can be prevented.

### Embodiment 2

Embodiment 2 is different from Embodiment 1 in that an irradiation mode can be selected when setting an observation condition. Hereinafter, Embodiment 2 will be described focusing on a difference from Embodiment 1.

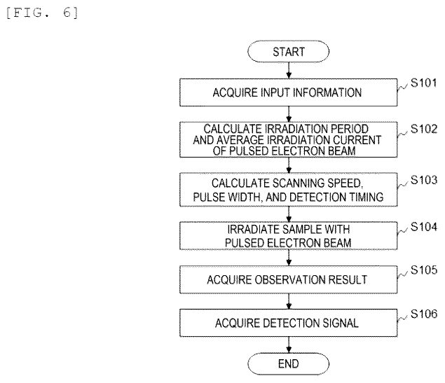

A configuration of the scanning electron microscope 10 of Embodiment 2 is the same as that in Embodiment 1. In Embodiment 2, the screen 500 is partially different. FIG. 7 is a diagram illustrating an example of a screen displayed on the output device 124 of Embodiment 2.

In Embodiment 2, two boxes are added to the input field 502. One box is a box for selecting an irradiation mode. In the box, “throughput” and “charge control” are displayed in a pull-down format. The other box is a parameter that can be set when the mode is “charge control”. A variable representing the parameter is denoted by Sep. Sep is an integer greater than or equal to 1 and less than or equal to a split distance.

A method for setting an observation condition of Embodiment 2 is the same as that in Embodiment 1, but formulae are partially different. Specifically, in Embodiment 2, a formula for calculating a pulse width is given by Formula (5).

$$\begin{matrix}[ Formula 5 ] & \\ {T}_{pls} = \frac{{I}_{ave} \times {T}_{ird}}{{I}_{p} \times Sep} & ( 5 )\end{matrix}$$

The other formulae are the same as those in Embodiment 1.

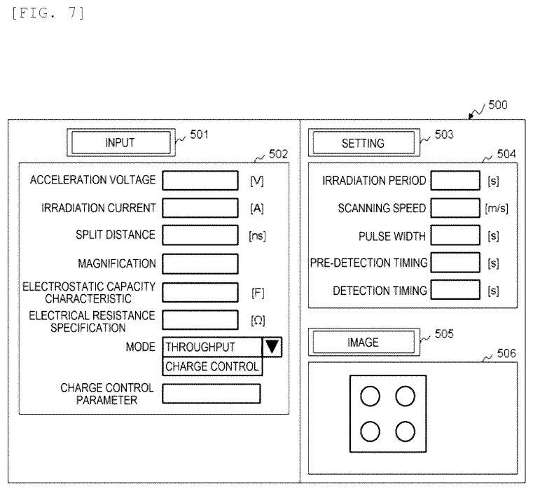

FIG. 8 is a diagram illustrating an example of a control signal of the scanning electron microscope 10 of Embodiment 2. In the charge control, a charge state of the sample 119 can be made uniform. Since an SN value decreases, the throughput decreases.

According to Embodiment 2, the observation condition can be set according to the irradiation mode.

### Embodiment 3

In Embodiment 3, a method for inputting an electrostatic capacity and an electrical resistance is different from that in Embodiment 1. Hereinafter, Embodiment 3 will be described focusing on a difference from Embodiment 1.

A configuration of the scanning electron microscope 10 of Embodiment 3 is the same as that in Embodiment 1. The computer 103 may not hold the observation range information 133.

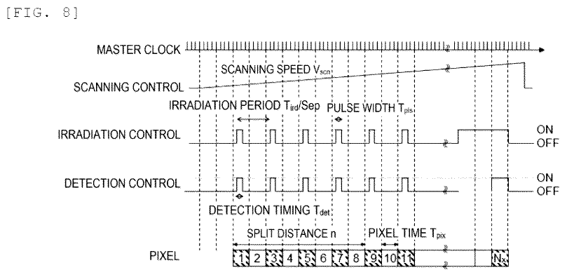

In Embodiment 3, the screen 500 is partially different. FIG. 9 is a diagram illustrating an example of a screen displayed on the output device 124 of Embodiment 3.

In Embodiment 3, the input field 502 includes a box for specifying a desired observation range instead of a box for inputting an electrostatic capacity and an electrical resistance. A user sets a desired observation range in a graph of the box. The desired observation range may be set numerically.

In Embodiment 3, the computer 103 performs calculation using an electrostatic capacity and an electrical resistance that correspond to a center of gravity of the set observation range. Contents of the calculation are the same as those in Embodiment 1.

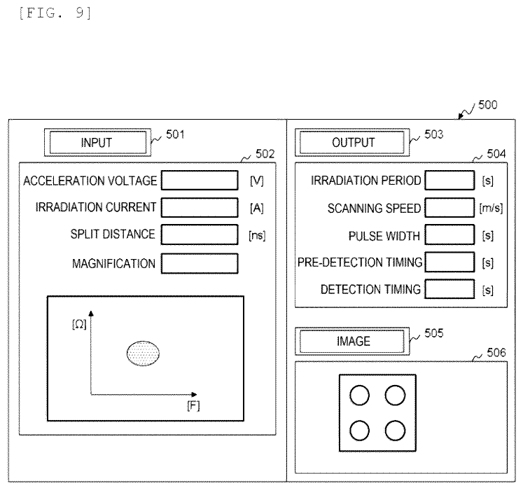

The following modifications are also conceivable. FIG. 10 is a flowchart illustrating a process executed by the scanning electron microscope 10 of Embodiment 3 when setting an observation condition.

Processes in step S101 to step S106 are the same as those in Embodiment 1.

In step S107, the computer 103 determines whether a desired result is obtained (step S107).

For example, the computer 103 calculates electric characteristics of the sample 109 based on a detection signal and determines whether the electric characteristics are included in a desired observation range. When the electric characteristics are not included in the desired observation range, the computer 103 determines that the desired result is not obtained.

When the desired result is not obtained, the computer 103 returns to step S102 and calculates an irradiation period and an average irradiation current. Specifically, the computer 103 grasps, based on the electric characteristics calculated based on the detection signal, a direction to move so as to include the electric characteristics in the desired observation range. The computer 103 adjusts, based on a deviation of the electric characteristics, the characteristic 1, and the characteristic 2, an irradiation period and an average irradiation current set in a current observation condition, and further calculates parameters (an irradiation period, a scanning speed, and a pulse width) for an irradiation control signal and parameters (a pre-detection timing and a detection timing) for a detection control signal using the adjusted irradiation period and average irradiation current.

When the desired result is obtained, the computer 103 ends the process.

According to Embodiment 3, the parameters (the irradiation period, the scanning speed, and the pulse width) for the irradiation control signal and the parameters (the pre-detection timing and the detection timing) for the detection control signal can be calculated based on the input of the desired observation range.

### Embodiment 4

In Embodiment 4, a method for inputting an electrostatic capacity and an electrical resistance and a method for setting an observation condition are different from those in Embodiment 1. Hereinafter, Embodiment 4 will be described focusing on differences from Embodiment 1.

A configuration of the scanning electron microscope 10 of Embodiment 4 is the same as that in Embodiment 1. The computer 103 may not hold the observation range information 133.

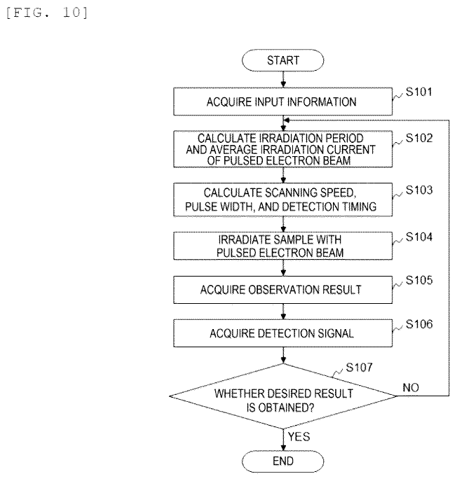

In Embodiment 4, the screen 500 is partially different. FIG. 11 is a diagram illustrating an example of a screen displayed on the output device 124 of Embodiment 4.

The input field 502 of Embodiment 4 includes a box for inputting a device structure of the sample 109 instead of a box for inputting an electrostatic capacity and an electrical resistance.

In Embodiment 4, the computer 103 performs a device simulation using a device structure to calculate a netlist. Further, the computer 103 calculates an electrostatic capacity and an electrical resistance based on the netlist.

The input field 502 of Embodiment 4 includes a box for inputting simulation setting information (a yield, a charge influence distance, an electric field on a sample, and a secondary electron energy distribution) for performing an observation simulation.

In Embodiment 4, the observation simulation is performed using an energy distribution model of an emitted electron having a potential saddle point generated by a surface potential due to charging.

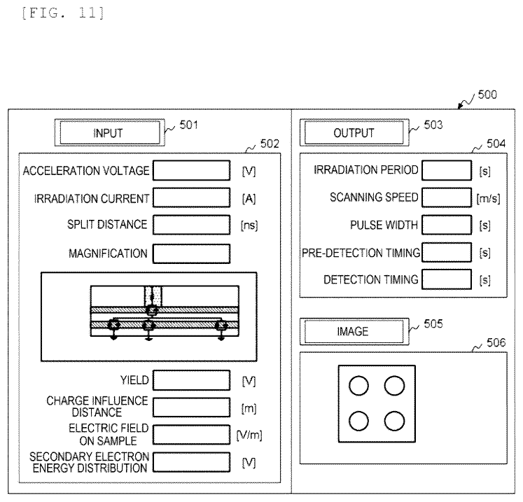

FIG. 12 is a diagram illustrating an example of a potential distribution used in the observation simulation of Embodiment 4.

In the model illustrated in FIG. 12, when the sample 119 is irradiated with a pulsed electron beam, a surface potential Vₛ depending on electric characteristics is generated on a surface of the sample 119, and a potential saddle point V_{φ} is generated due to an interaction between an electric field in a Z direction of the sample 119 and a surface potential. The potential saddle point is a negative potential with respect to the surface potential, and therefore acts as an energy barrier for an emitted electron. The energy barrier is given as a difference between the potential saddle point and the surface potential. As the surface potential increases, an emission current (a signal intensity) of an emitted electron decreases, and a charging capability decreases.

At this time, a current Iₛₑ of an emitted electron is defined by Formula (6).

$$\begin{matrix}[ Formula 6 ] & \\ {I}_{se} = {I}_{p} ( ( 1 - exp ( - \frac{{V}_{φ} - {V}_{s}}{β} ) ) σ ) & ( 6 )\end{matrix}$$

Here, β is a variable representing a characteristic parameter of an energy distribution of an emitted electron, and σ is a variable representing a yield.

When an equivalent circuit corresponding to the sample 119 is connected to a pulsed electron beam controlled based on Formula (6), a current source corresponds to an emission current of the emitted electron, so that the observation simulation can be performed. For example, by modeling a contact plug of a semiconductor substrate with a parallel circuit, a time change of the emission current of the emitted electron can be simulated based on electric characteristics of the contact plug.

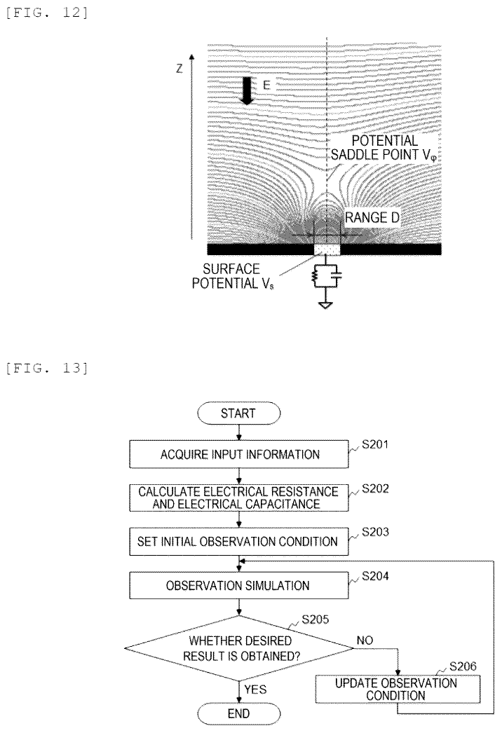

FIG. 13 is a flowchart illustrating a process executed by the scanning electron microscope 10 of Embodiment 4 when setting an observation condition.

The computer 103 acquires input information including values input to the input field 502 (step S201).

The computer 103 calculates electric characteristics by executing a device simulation using a device structure of the sample 109 included in the input information (step S202).

The computer 103 sets an initial observation condition (step S203).

As an acceleration voltage, an irradiation current, a split distance, and a magnification, values included in the input information are used. The other parameters are determined randomly or based on any algorithm. A parameter range may be specified in advance.

The computer 103 executes the observation simulation based on the observation condition and the simulation setting information included in the input information (step S204).

The computer 103 determines, based on the electric characteristics calculated based on the netlist and the electric characteristics obtained from the observation simulation, whether a desired result is obtained (step S205). For example, when an error between the two electric characteristics is smaller than a threshold value, the computer 103 determines that the desired result is obtained.

When the desired result is not obtained, the computer 103 updates the observation condition based on the electric characteristics calculated based on the netlist and the electric characteristics obtained from the observation simulation (step S206), and then returns to step S204.

Specifically, the computer 103 can grasp, in an (electrostatic capacity-electrical resistance) space, a direction for bringing the electrical characteristics obtained from the observation simulation closer to the electrical characteristics calculated based on the netlist. The computer 103 adjusts, based on a deviation of the electric characteristics, the characteristic 1, and the characteristic 2, an irradiation period and an average irradiation current set in a current observation condition, and further calculates parameters (an irradiation period, a scanning speed, and a pulse width) for an irradiation control signal and parameters (a pre-detection timing and a detection timing) for a detection control signal using the adjusted irradiation period and average irradiation current.

In this way, by using the characteristic 1 and the characteristic 2, the observation condition can be adjusted efficiently and quickly.

When the desired observation result is not obtained, the computer 103 ends the process.

According to Embodiment 4, the observation condition can be appropriately set even when the characteristics of the sample 119 are unknown and the observation range map 400 does not exist.

### Embodiment 5

In Embodiment 5, a configuration of the scanning electron microscope 10 is different from that in Embodiment 1. Hereinafter, Embodiment 5 will be described focusing on a difference from Embodiment 1.

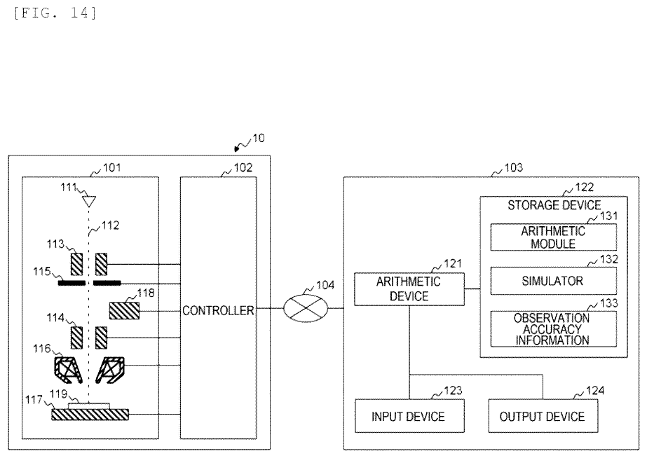

FIG. 14 is a diagram illustrating an example of the configuration of the scanning electron microscope 10 of Embodiment 5.

In Embodiment 5, the scanning electron microscope 10 does not include the computer 103. The scanning electron microscope 10 communicates with the computer 103 via a network 104. The computer 103 may be replaced with, for example, a cloud system.

In Embodiment 5, the computer 103 displays the screen 500 for the scanning electron microscope 10 and receives an input. After acquiring input information via the screen 500, the computer 103 executes processes from step S102 to step S106.

The computer 103 may perform any one of processes in Embodiment 2 to Embodiment 4.

The invention is not limited to the embodiment described above, and includes various modifications. For example, the embodiment described above is described in detail to facilitate understanding of the invention, and the invention is not necessarily limited to those including all the described configurations. A part of a configuration in each embodiment may be added to, deleted from, or replaced with another configuration.

A part or all of the configurations, functions, processing units, processing methods, and the like described above may be implemented by hardware by, for example, designing with an integrated circuit. The invention can also be implemented by a program code of software for implementing the functions of the embodiments. In this case, a storage medium storing the program code is provided to a computer, and a processor provided in the computer reads the program code stored in the storage medium. In this case, the program code read from the storage medium implements the functions of the embodiments described above by itself, and the program code itself and the storage medium storing the program code implement the invention. Examples of the storage medium for supplying such a program code include a flexible disk, a CD-ROM, a DVD-ROM, a hard disk, a solid state drive (SSD), an optical disk, a magneto-optical disk, a CD-R, a magnetic tape, a non-volatile memory card, and a ROM.

Further, the program code for implementing the functions described in the present embodiment can be implemented in a wide range of programs or script languages such as assembler, C/C++, Perl, Shell, PHP, Python, and Java.

Further, the program code of software for implementing the functions of the embodiments may be distributed via a network to be stored in a storage unit such as a hard disk or a memory of a computer or a storage medium such as a CD-RW or a CD-R, and a processor provided in the computer may read and execute the program code stored in the storage unit or the storage medium.

Control lines and information lines considered to be necessary for description are shown in the embodiment described above, and not all control lines and information lines are necessarily shown in a product. All the components may be connected to each other.

1. A charged particle beam device for observing a sample by periodically irradiating the sample with a pulsed charged particle beam, the charged particle beam device comprising:
a particle source configured to output the charged particle beam;
a lens configured to focus the charged particle beam;
a detector configured to detect a signal of an emitted electron emitted from the sample irradiated with the charged particle beam; and
a control device configured to control the irradiation using the pulsed charged particle beam and the detection of the signal of the emitted electron based on an observation condition, wherein
the control device
calculates an irradiation period, a scanning speed, and a pulse width of the pulsed charged particle beam and a detection timing of the signal of the emitted electron based on a current of the charged particle beam emitted from the particle source and an electrostatic capacity and an electrical resistance of the sample, and
sets the observation condition including the current of the charged particle beam, the irradiation period, the scanning speed, and the pulse width of the pulsed charged particle beam, and the detection timing of the signal of the emitted electron.

2. The charged particle beam device according to claim 1, wherein
the control device holds observation range information for managing an observation range map representing observation accuracy for a combination of the electrical resistance and the electrostatic capacity of the sample,
the observation range map is managed in association with the irradiation period and an average irradiation current, which is a current to be applied to the sample in one period, and
the control device
specifies, based on the electrical resistance and the electrostatic capacity of the sample and the observation range map, the observation range map allowing accurate observation,
acquires the irradiation period and the average irradiation current associated with the observation range map, and
calculates the scanning speed, the pulse width, and the detection timing of the signal of the emitted electron based on the acquired irradiation period and the acquired average irradiation current.

3. The charged particle beam device according to claim 2, wherein
the control device
receives an input of a parameter for controlling a charge state of the sample, and
calculates the scanning speed, the pulse width, and the detection timing of the signal of the emitted electron based on the acquired irradiation period, the acquired average irradiation current, and the parameter.

4. The charged particle beam device according to claim 1, wherein
the control device
calculates the electrical resistance and the electrostatic capacity of the sample based on a device structure of the sample,
sets the observation condition and simulates observation of the sample, and
updates the observation condition by changing the irradiation period and an average irradiation current, which is a current to be applied to the sample in one period, in the current observation condition based on an error between the calculated electrical resistance and electrostatic capacity of the sample and the electrical resistance and electrostatic capacity of the sample obtained by the simulation.

5. A method for setting an observation condition for a charged particle beam device for observing a sample by periodically irradiating the sample with a pulsed charged particle beam, the charged particle beam device including:
a particle source configured to output the charged particle beam,
a lens configured to focus the charged particle beam,
a detector configured to detect a signal of an emitted electron emitted from the sample irradiated with the charged particle beam, and
a control device configured to control the irradiation using the pulsed charged particle beam and the detection of the signal of the emitted electron based on an observation condition, the method for setting an observation condition comprising:
a first step of the control device calculating an irradiation period, a scanning speed, and a pulse width of the pulsed charged particle beam and a detection timing of the signal of the emitted electron based on a current of the charged particle beam emitted from the particle source and an electrostatic capacity and an electrical resistance of the sample; and
a second step of the control device setting the observation condition including the current of the charged particle beam, the irradiation period, the scanning speed, and the pulse width of the pulsed charged particle beam, and the detection timing of the signal of the emitted electron.

6. The method for setting an observation condition according to claim 5, wherein
the control device holds observation range information for managing an observation range map representing observation accuracy for a combination of the electrical resistance and the electrostatic capacity of the sample,
the observation range map is managed in association with the irradiation period and an average irradiation current, which is a current to be applied to the sample in one period, and
the first step includes
a third step of the control device specifying the observation range map allowing accurate observation based on the electrical resistance and the electrostatic capacity of the sample and the observation range map,
a fourth step of the control device acquiring the irradiation period and the average irradiation current associated with the observation range map, and
a fifth step of the control device calculating the scanning speed, the pulse width, and the detection timing of the signal of the emitted electron based on the acquired irradiation period and the acquired average irradiation current.

7. The method for setting an observation condition according to claim 6, wherein
the first step includes a step of the control device receiving an input of a parameter for controlling a charge state of the sample, and
the fifth step includes a step of the control device calculating the scanning speed, the pulse width, and the detection timing of the signal of the emitted electron based on the acquired irradiation period, the acquired average irradiation current, and the parameter.

8. The method for setting an observation condition according to claim 5, wherein
the first step includes
a step of the control device calculating the electrical resistance and the electrostatic capacity of the sample based on a device structure of the sample,
a step of the control device setting the observation condition and simulates observation of the sample, and
a step of the control device updating the observation condition by changing the irradiation period and an average irradiation current, which is a current to be applied to the sample in one period, in the current observation condition based on an error between the calculated electrical resistance and electrostatic capacity of the sample and the electrical resistance and electrostatic capacity of the sample obtained by the simulation.

9. A program for causing a computer to set an observation condition for a charged particle beam device for observing a sample by periodically irradiating the sample with a pulsed charged particle beam, the charged particle beam device including:
a particle source configured to output the charged particle beam,
a lens configured to focus the charged particle beam,
a detector configured to detect a signal of an emitted electron emitted from the sample irradiated with the charged particle beam, and
a control device configured to control the irradiation using the pulsed charged particle beam and the detection of the signal of the emitted electron based on an observation condition, the program causing the computer to execute:
a first procedure of calculating an irradiation period, a scanning speed, and a pulse width of the pulsed charged particle beam and a detection timing of the signal of the emitted electron based on a current of the charged particle beam emitted from the particle source and an electrostatic capacity and an electrical resistance of the sample; and
a second procedure of setting the observation condition including the current of the charged particle beam, the irradiation period, the scanning speed, and the pulse width of the pulsed charged particle beam, and the detection timing of the signal of the emitted electron.

10. The program according to claim 9, wherein
the computer holds observation range information for managing an observation range map representing observation accuracy for a combination of the electrical resistance and the electrostatic capacity of the sample,
the observation range map is managed in association with the irradiation period and an average irradiation current, which is a current to be applied to the sample in one period, and
the first procedure includes
a third procedure of specifying the observation range map allowing accurate observation based on the electrical resistance and the electrostatic capacity of the sample and the observation range map,
a fourth procedure of acquiring the irradiation period and the average irradiation current associated with the observation range map, and
a fifth procedure of calculating the scanning speed, the pulse width, and the detection timing of the signal of the emitted electron based on the acquired irradiation period and the acquired average irradiation current.

11. The program according to claim 10, wherein
the first procedure includes a procedure of receiving an input of a parameter for controlling a charge state of the sample, and
the fifth procedure includes a procedure of calculating the scanning speed, the pulse width, and the detection timing of the signal of the emitted electron based on the acquired irradiation period, the acquired average irradiation current, and the parameter.

12. The program according to claim 9, wherein
the first procedure includes
a procedure of calculating the electrical resistance and the electrostatic capacity of the sample based on a device structure of the sample,
a procedure of setting the observation condition and simulates observation of the sample, and
a procedure of updating the observation condition by changing the irradiation period and an average irradiation current, which is a current to be applied to the sample in one period, in the current observation condition based on an error between the calculated electrical resistance and electrostatic capacity of the sample and the electrical resistance and electrostatic capacity of the sample obtained by the simulation.
